(19) United States
(12) Patent Application Publication
(10) Pub. No.: US 2008/0072421 A1
(43) Pub. Date: Mar. 27, 2008

(54) Molded Substrate for Topography Based Lithography

(76) Inventor: Daniel Robert Shepard, North Hampton, NH (US)

Correspondence Address: GOODWIN PROCTER LLP;PATENT ADMINISTRATOR, EXCHANGE PLACE, BOSTON, MA, 02109-2881, US

(21) Appl. No.: 11/938,945

(22) Filed: Nov. 13, 2007

Related U.S. Application Data
(62) Division of application No. 10/922,256, filed on Aug. 19, 2004, now abandoned.
(60) Provisional application No. 60/496,272, filed on Aug. 19, 2003.

(51) Int. Cl. H05K 3/10; B23P 19/00

(52) U.S. Cl. 29/846; 29/745; 29/831

(57) ABSTRACT

The present invention is a means for forming substrates for the fabrication of active devices using topography based lithographic manufacturing techniques. A form is used to create a substrate by injection molding, embossing, or by other means of applying a topography to the substrate using a form. This substrate can be plastic, glass or other moldable material or a moldable material layer on another material, but is typically an insulating material that will not participate in the operation of the end devices. The present invention is a means for creating such a form. Furthermore, the present invention is also a means for molding the backside of said substrate, either simultaneously or in multiple steps, such that active devices or portions of a given active device can be formed on both front and back sides of the substrate. The present invention includes means for interconnecting components on both sides of the substrate. This invention will find application to the forming of substrates for the purpose of fabricating memory devices having preprogrammed content (i.e., factory Programmed Read Only Memory, PROM) and includes means for adding such content at a later point in the process to create such a form for economic advantage. Finally, the present invention includes means for making such a memory device as a removable and interchangeable component for insertion into industry standard or proprietary form factors (e.g., a CompactFlash™ card) or other adapting devices (e.g., a GPS card) whereby the particular form factor would act as a carrier device into which the memory device is inserted and then the carrier device is plugged into an accessing device (e.g., a music or media player, a computing device, or the like). Alternatively, the adapting mechanism could be a permanent part of the accessing device.

### CROSS-REFERENCE TO RELATED PATENT AND PATENT APPLICATION

This application makes references to U.S. Pat. No. 6,586,327 for “Fabrication of Semiconductor Devices”, issued Jul. 1, 2003 and this application claims the benefits of U.S. Provisional Application No. 60/496,272, filed on Aug. 19, 2003, and those documents in their entirety are hereby incorporated herein by reference.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### FIELD OF THE INVENTION

The present invention is a method for forming substrates for the fabrication of active devices, and in particular for forming substrates for the fabrication of active devices using topography based lithographic manufacturing techniques.

### SUMMARY OF THE INVENTION

A method for forming active devices such as memory circuits has been disclosed in the prior art in U.S. Pat. No. 6,586,327. This process is run on a substrate having a topography that defines the end resulting devices. A form is used to create a substrate by injection molding, embossing, or by other means of applying a topography to the substrate using a form. This substrate can be plastic, glass or other moldable material or a moldable material layer on a substrate of another material, but is typically an insulating material that will not participate in the operation of the end devices. The present invention is a means for creating and using such a form.

Not only is the present invention a means for creating such a form for the surface, but the present invention is also a means for molding the backside of the substrate, either simultaneously or in multiple steps, such that active devices or portions of a single active device can be formed on both front and back sides of the substrate. The present invention includes means for interconnecting components on both sides of the substrate.

The present invention will find application to the forming of substrates for the purpose of fabricating memory devices having preprogrammed content (i.e., factory Programmed Read Only Memory, PROM) and includes means for adding such content at a later point in the process to create such a form for economic advantage. Finally, the present invention includes means for making such a memory device as a removable and interchangeable component for insertion into industry standard or proprietary form factors (e.g., a CompactFlash™ card) or other adapting devices (e.g., a GPS card) whereby the particular form factor would act as a carrier device into which the memory device is inserted and then the carrier device is plugged into an accessing device (e.g., a music or media player, a computing device, or the like). Alternatively, the adapting mechanism could be a permanent part of the accessing device.

### BRIEF DESCRIPTION OF THE DRAWINGS

FIG. 1. illustrates a portion of a stamper for a substrate having four different depth features in its topography positioned above said substrate.

FIG. 2. illustrates the formation of features having non-vertical sidewall angles.

FIG. 3. illustrates the programming of data as would occur when said data bits are programmed onto a previously formed stamper.

FIG. 4 illustrates the formation of connections through the molded substrate to facilitate the incorporation of backside bonding pads or dual-sided circuitry.

### DESCRIPTION OF THE PREFERRED EMBODIMENT

The present invention is a means for creating a form for molding a topography onto a substrate. A substrate so created with a topography will have deposited on it one or more layers of materials, the top layer of which is typically an etch resistant (or slow etching) material. These materials are then planarized and further processed, typically by etching. The substrate is formed by injection molding, embossing, or by other means of applying a topography to the substrate using a form.

One method for forming a topography on a substrate using a form is that used in the manufacture of CD-ROM and DVD. In particular, a master is created using photolithographic processing techniques. A glass substrate is coated with photoresist using a spinner deposition process. This glass substrate is turned while a laser is modulated thereby writing a pattern on the photoresist; with each revolution of the glass substrate, the laser moves radially outward so as to create concentric rings of data bits. The glass master is then developed in a developer solution resulting in either a collection of pits in a field of resist corresponding to the data bits or a collection of photoresist mesas depending upon whether positive or negative photoresist is used. In the case of pits in a field of resist, the glass substrate with its pitted field of resist is thinly plated with a film of nickel and this film is then increased in thickness to a few hundred microns by electroplating. This thickened nickel plate is then separated from the glass substrate either mechanically or chemically and is cleaned of any photoresist that might stick to it (as is the glass master for reuse). This nickel plate is the form (called a stamper) that would be inserted into an injection molding machine for the mass production of CD-ROM or DVD substrates.

In the case of the present invention, a substrate would be created using photolithography or e-beam lithography or the like to pattern a silicon or other material substrate. Silicon substrates are preferred due to the well understood processing techniques that have been developed by the semiconductor manufacturing industry. A multilevel topography is formed into the substrate through a series of photolithographic exposures and etching steps. This series of steps would be determined by the desired end result.

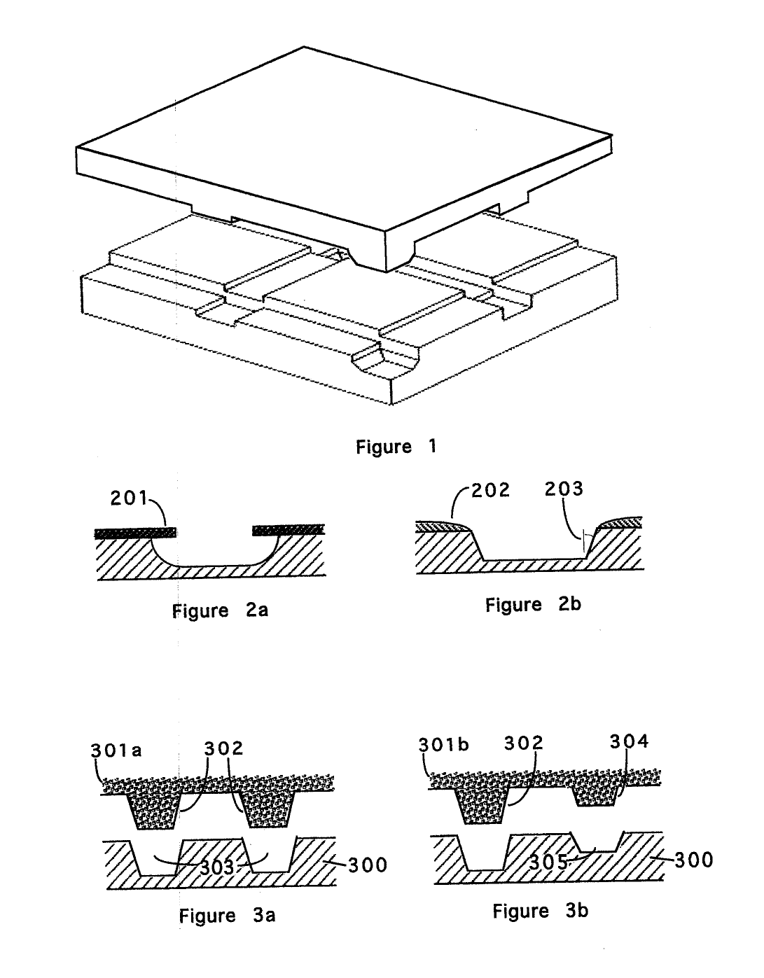

An electronic storage matrix having a diode or some other two terminal device (e.g., an SCR with no gate connections) at some points in the array and a non-connecting crossover of row and column at the remaining points (as is described in U.S. Pat. No. 6,586,327) would have four different depth topography features; a portion of such a substrate is shown in FIG. 1. One would typically start by patterning and etching a plurality of parallel rows to a first depth. This would be followed by patterning and etching to a second depth approximately twice the depth of the first etch a plurality of columns that are aligned and perpendicular to the rows. The result of these two steps would be to also create a feature having a third depth at the points of intersection of the rows and columns that would correspond to the crossovers; the depth of this third feature would be roughly equal to the sum of the first two depth features (but, might be slightly less deep due to a loading effect of certain etch processes as the feature depth increases). Finally, a third aligned patterning and etching to a forth depth feature consisting of a pit placed in those points of intersection of the rows and columns that are desired to correspond to a two terminal device as opposed to a crossover. This etch would be roughly as deep as the first etch resulting in four depth features whereby the four depths are roughly integer multiples of the first depth feature.

If the etch is performed with a wet etch process, the sidewalls will be curved, as opposed to the generally vertical etch typically created with a dry etch such as reactive ion etch (RIE), and this contour will aid both in creating continuous metal film traces in a subsequent topography based lithographic process as well as in providing a means for more easily releasing a molded substrate from the stamper during substrate formation. As is shown in FIG. 2a, a wet etch will undercut the etch mask 201 as it etches downward. Alternatively as is shown in FIG. 2b, a dry etch such as a RIE could be employed whereby oxygen gas is included in the etch chemistry so as to etch back the photoresist 202 (thereby widening the features developed into the photoresist as the etch progresses) resulting in a tapered, or reentrant, sidewall profile. A sidewall angle 203 of approximately 12 degrees (though greater angles and smaller angles are possible) is used in the manufacture of CD-ROM's to enable effective stamper and substrate separation. This substrate would then be plated with nickel (as is done with CD-ROM stampers) and then the silicon substrate would be chemically etched using a variety of processes as is well known to those skilled in the art of semiconductor manufacturing. For example, the substrate could be soaked in the etchant KOH that dissolves silicon but does not etch nickel. This nickel plate could be used as a stamper to form substrates that have generally the same topography as the silicon substrate master. These molded substrates can then be used in a topography based lithographic process. Alternatively, the master could be used to create father, mother, and child copies as is well understood in the fabrication of CD-ROM's and DVD's so that more than one stamper could be created from the single original master.

If this diode array is to be used as a part of a factory Programmed Read Only Memory device, the pattern of diodes and crossovers could be created in the master. However, if the master is used to create 10 to 100 stampers and each stamper can typically mold 80,000 to 750,000 substrates, as many as 75 million identical substrates might be created. This might not be necessary. An alternative approach, as shown in FIG. 3, would be to create the master as if a diode or some other two terminal device was desired at every point of intersection in the storage array and proceed to create the stampers. As shown in FIG. 3a, these stampers 301a will have a mesa 302 or raised post at every location where a topographical feature 303 for a diode or some other two terminal device is to be formed (corresponding to, say, a one bit in the data stored in the array) in substrate 300. To convert a one bit to a zero bit, one would simply have to spin up the stamper disk with photoresist and, using a mask and standard photolithography or a laser or an e-beam writer, expose the resist at every point where a mesa exists that is desired to be changed from a one bit to a zero bit. The photoresist is then developed so as to remove the photoresist from on top of those mesas and the stamper 301b is then etched such that those mesas are etched back 304 to the height suitable for forming a topographical feature 305 for a crossover.

Once the stamper is created, it can be inserted into an injection molding machine to form substrates. In an injection molding process, a chamber having the stamper mounted within is filled with liquified material and is then compressed to press the pattern of the stamper into the material. The material is allowed to cool to the point that it can hold the pattern pressed therein and the chamber is opened and the molded substrate is removed.

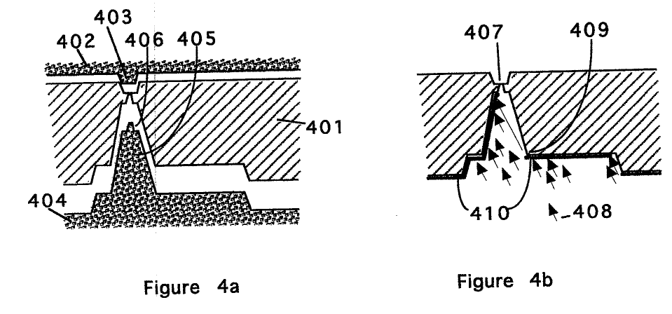

Referring now to FIG. 4, it is envisioned by the present invention that two stampers 402 and 404 could be mounted opposite each other in the chamber such that the substrate 401 could be simultaneously patterned on both the front and back sides. This would be useful for forming a larger active device by using both substrate sides together or for providing connection points (e.g., contact or bonding pads) on the side opposite any active devices. This may necessitate the providing of connections from one side to the other which could be done by placing small mesas 406 on larger area (for strength) mesas 405 on the second stamper 404 such that when the mold is closed and compressed, those small mesas 406 would be tall enough to almost (or lightly) touch the first stamper at molding mesa points 403 where the through connections are to be made. As is shown in FIG. 4b, a thin membrane of substrate material 407 that would remain across the through opening to support the front side processing. The front side process would have material in the topographical feature formed on the front side by mesa 403. Following front side processing, this thin membrane would be removed in order to expose said material in the topographical feature formed on the front side by mesa 403 to which a connection will be made (typically, this material would comprise a layer of an etch resistant material such as chrome or nickel to act as an etch stop during the thin membrane removal). This thin membrane material (and potentially some of said material up to said layer of etch resistant material) would be removed by etching the substrate from the backside enough to etch through the thin membranes at the thickest point (which would also remove a bit of the surface material everywhere on that backside). It is also possible to process the backside first and etch the front side in order to remove any membrane material, but this is considered less desirable because of the potential impact such a front side etch may have on the front side topography or the added complexity of incorporating the membrane removal during front side processing. It should be noted that the front and rear features with which a through connection is to be made will typically be designed with a larger area—this is because these features will have to be aligned (front side to back side) and larger sized features will better facilitate this alignment.

If any etching of the backside material was undesirable, a thin layer of etch resistant material 410 such as chrome or nickel could be evaporated by e-beam or other methods onto the backside at an angle 408 such that the entire backside would be coated by the etch resistant material except for where said angle, by virtue of other features 409 blocking the deposition path, would prevent the etch resistant material from coating the bottoms of such features as the pits, the through openings, or the remaining membrane film thereby protecting all areas from the etch except for said areas left uncoated; this etch resistant material could be chemically removed or, in the case of contact or bonding pads where each pad is molded as a recessed area on the backside having a through opening to the opposite side, the etch resistant material could be used as a starting layer for the bonding pad which could be defined through electroplating to fill the bonding pad topographical feature followed by a damascene-like backside planarization to separate and define the individual bonding pads). Alternatively, the substrate might be molded in two steps: first the backside might be molded (say, in a glass substrate) and this substrate might then be processed with a metal fill pattern (comprising, if desired, a layer of etch resistant material) and damascene planarized to define the back side pattern; second, the front side might be planarized so as to expose the through contact material and provide a very flat surface to better facilitate subsequent front side processing; third the front side might be thinly coated (e.g., a micron or so thick) with a moldable material (such as Ultra, a GE Plastics product); and, finally, the thin coat of moldable material on the front side would be patterned with a topography and processed wherein said processing would comprise removal of the thin coat of moldable material at those locations where the through contact material is exposed such that the front side materials can form a connection to the back side material.

Once the substrate is molded, it can be used in a topography based lithographic process. If the backside is also patterned, backside processing will also have to be performed. Deep features could be molded between die to enable the dicing of chips by snapping (or cutting) the substrate along these features. A device fabricated with large contact pads on the backside could be used as a final packaged device by bonding a package top to the active device side to protect the circuits and leaving the backside contacts exposed. The dicing of fully packaged devices could be done following the bonding of the package top material thereby enabling package assembly to be performed at the wafer level instead of by individual devices.

This packaged device could be removably inserted into an industry standard (or proprietary) form factor having mating contacts complementary to the packaged device thereby enabling the packaged device to be accessible within a wide variety of systems without having to incorporate all the support packaging and control logic of that form factor with each individual packaged device. This industry standard (or proprietary) form factor would most likely comprise controller logic and, potentially, a buffer memory space. Such a memory space would be potentially useful in the case that the packaged device to be inserted in this industry standard (or proprietary) form factor is a one time programmable memory device, in which case the buffer could hold content (such as the data for a photographic image) such that said content could be reviewed by the user for acceptability prior to being transferred into permanent storage in the packaged device. Such transfer to permanent storage could be initiated by the user by pushing a button that is either directly connected to the industry standard (or proprietary) form factor, to the device into which the industry standard (or proprietary) form factor has been inserted or through other connections or by wireless means. Alternatively, for the most transparent operation to the user, the transfer could be initiated by the arrival of new data (provided that the prior data had not been deleted); the user would, in the case of a photographic system, just take pictures and each one would be permanently stored unless the user acted to delete one. Deletion could likewise be affected by the user by pushing a button that is either directly connected to the industry standard (or proprietary) form factor, to the device into which the industry standard (or proprietary) form factor has been inserted or through other connections or by wireless means. The transfer might also be initiated following the passage of some period of time—this particular mechanism would be most useful if the buffer memory space comprised volatile memory. Furthermore, if the packaged device is any type of memory device as opposed to just a one time programmable memory device, the buffer memory space could be used to hold data read from the packaged device in order to facilitate the processing or transformation of that data into a form that is uncompressed (if the data was stored compressed), decrypted (if the data was stored encrypted), and/or error corrected (if the data was stored with error correcting bits) so that the plain form of the data can be read from the industry standard (or proprietary) form factor at the convenience of the device into which the industry standard (or proprietary) form factor has been inserted (conversely, the buffer memory space could be used to hold data moving in the opposite direction while it is being compressed, encrypted and/or enhanced with error correcting bits prior to being written into permanent storage in the packaged device). The packaged device could alternatively be inserted into any system having the corresponding mating contacts to the packaged device. Of course, all of the benefits of the incorporation of such buffer memory space would apply equally well in the event that the packaged device was permanently incorporated within and not removable from the industry standard (or proprietary) form factor. The implementation details of these variations will be obvious to one skilled in the art.

1. A device for applying to a material a plurality of patterns each defining an electrical circuit, the device comprising a plurality of surfaces each comprising a master pattern complementary to an electrical circuit pattern to be applied to said material, wherein each master pattern comprises raised features for producing complementary recessed features and a height of a raised feature and a depth of a corresponding recessed feature indicate one or more bits of information.

2.-3. (canceled)

4. The device of claim 1, wherein the plurality of surfaces comprises first and second opposed surfaces.

5. (canceled)

6. The device of claim 13, wherein at least one of the raised features is alterable prior to applying the pattern to the material to program the resulting one or more bits of information represented by the at least one of the recessed features.

7. The device of claim 4, wherein one of the patterns determines at least a portion of the packaging of the electrical circuit defined thereby.

8.-12. (canceled)

13. The device of claim 1, wherein at least some of the recessed features produced by the plurality of surfaces meet through the material.

14. A method of making a device for applying to a material a plurality of patterns each defining an electrical circuit, the method comprising the steps of:
providing a substrate comprising a plurality of opposed surfaces; and
applying, on each surface, a master pattern complementary to an electrical circuit,
wherein each master pattern comprises raised features for producing complementary recessed features and a height of a raised feature and a depth of a corresponding recessed feature indicates one or more bits of information.

15. The method of claim 14, wherein at least one of the master patterns is formed through photolithographic processing.

16. The method of claim 14, wherein at least one of the master patterns is formed by a controlled ion beam.

17. The method of claim 14, wherein at least some of the recessed features from each master pattern meet through the material.

18. The method of claim 14, further comprising altering at least one of the raised features prior to applying the pattern to the material to thereby program the resulting bit of information represented by the corresponding at least one recessed feature.

19. A method of making a circuit pattern, the method comprising the steps of:
applying to a first surface of a material a first pattern defining an electrical circuit; and
applying to a second surface of the material a second pattern defining an electrical circuit, the first and second surfaces being opposed to each other,
wherein the first pattern and second pattern each comprise recessed features indicating one or more bits of information.

20. The method of claim 19, wherein the first pattern and the second pattern each comprise recessed features of differing depths, at least some of the recessed features of the first pattern meeting complementary recessed features of the second pattern to facilitate electrical communication therebetween.
